(19) United States
(12) Patent Application Publication
(10) Pub. No.: US 2013/0344612 A1
(43) Pub. Date: Dec. 26, 2013

(54) ULTRASENSITIVE, SUPERFAST, AND MICROLITER-VOLUME DIFFERENTIAL SCANNING NANOCALORIMETER FOR DIRECT CHARACTIZATION OF BIOMOLECULAR INTERACTIONS

(71) Applicant: THE RESEARCH FOUNDATION OF STATE UNIVERSITY OF NEW YORK, Albany, NY (US)

(72) Inventor: Lei ZUO, Nesconset, NY (US)

(21) Appl. No.: 13/923,052

(22) Filed: Jun. 20, 2013

Related U.S. Application Data
(60) Provisional application No. 61/662,127, filed on Jun. 20, 2012.

(51) Int. Cl. G01N 25/48; H01L 37/00

(52) U.S. Cl. CPC G01N 25/4806; H01L 37/00
USPC 436/147; 422/51; 438/54

(57) ABSTRACT

Disclosed is a differential scanning nanocalorimeter device, methods of fabricating such a device, and methods of use thereof. The nanocalorimeter contains thermal equilibrium areas for sample and reference liquids, with thermometers, compensation heater, and electric trace elements fabricated on a free-standing polymer diaphragm membrane.

### CROSS-REFERENCE TO RELATED APPLICATIONS

This application claims priority to U.S. provisional application 61/662,127, filed Jun. 20, 2012, which is incorporated herein in its entirety.

### BACKGROUND OF THE DISCLOSURE

All biological phenomena depend on molecular interactions. Molecular interactions can be intermolecular, such as a ligand binding to a protein, or intramolecular, such as protein folding. Modern instrumentation for calorimetry permits direct characterization of the thermodynamic profiles of molecular interactions including Gibbs free energy, enthalpy, entropy, specific heat, and stoichiometry, which provides enormously valuable information to rational drug design and biological mechanism study that cannot be obtained from structural or computational methods alone. However, the current state of the art calorimeters require a large volume of protein, and require a long measurement time.

There exists a need for improved calorimeters for measuring biological phenomena.

### BRIEF SUMMARY OF THE DISCLOSURE

Disclosed herein is a new and improved differential scanning nanocalorimeter, which is capable of measuring thermal fluctuations of 10 μK or even less, in a small sample size.

The disclosed nanocalorimeter has at its core a polymer diaphragm with a plurality of thermal equilibrium areas for measuring molecular interactions. Each thermal equilibrium area includes at least one compensation heater and at least one microthermistor, preferably four microthermistors. The at least one microthermistor is formed from a microthermistor trace that is sandwiched between additional electrically conductive trace. The microthermistor trace can be made from one or more of silicon carbide, amorphous silicon carbide, diamond, amorphous germanium, or silicon-germanium-boron alloy. The additional electrically conductive traces on either side of the microthermistor trace can be composed, for example, of chromium, gold, or a chromium-gold alloy.

The polymer diaphragm can be free-standing, that is, the diaphragm holds and connects the thermal equilibrium areas to the rest of the nanocalorimeter, with at least a portion of the diaphragm surrounding the thermal equilibrium areas unattached to any conductive material. In this way, the diaphragm, which is made of a low- or non-conductive material, isolates temperature changes within the thermal equilibrium area or areas by creating an “island” of conductive material associated with the thermal equilibrium area or areas, separated by a “sea” of non-conductive polymer. This free-standing diaphragm thus improves the sensitivity of the nanocalorimeter. The polymer diaphragm can be made of epoxy resin, such as SU-8 photoresist or a polyimide film. In a preferred example, the epoxy resin is SU-8 with a thickness of about 20 μm. The polymer diaphragm can further include a copper island on the underside of each thermal equilibrium area.

The disclosed nanocalorimeter may further have a cap or cover made of a suitable material, such as PDMS (polydimethylsiloxane), which can encompass all or part of the device.

Further disclosed herein are nanocalorimeter arrays with a plurality of nanocalorimeters. Such an array can be used, for example, for high-throughput measurements.

Also disclosed are methods of measuring thermodynamic changes induced by molecular interactions, comprising applying a sample of biological material to the nanocalorimeter of claim 1 and measuring the change in temperature resulting from the molecular interaction. Preferably, the biological sample has a volume of 5 μl or less.

Further disclosed are methods of making a nanocalorimeter according to the invention. The methods include the steps of:
a. providing a semiconductor substrate;
b. patterning the substrate and etching the back side of the substrate to define a diaphragm window;
c. forming a thermistor trace on the front side of the substrate over the area defining the diaphragm window;
d. depositing feedback heater material on the front side of the substrate over the area defining the diaphragm window;
e. forming electrically conductive traces along either side of the thermistor trace to sandwich the thermistor trace between electrically conductive trace;
f. depositing a polymer superstrate on the front side of the substrate to encapsulate the thermistor trace, feedback heater, and electrically conductive trace; and
g. further etching the area defining the diaphragm window on the back side of the substrate to form a free-standing polymer diaphragm.

The method can further include the step of: (h) forming a copper island on the back side of the substrate within the area defining the diaphragm window.

According to this method, the semiconductor substrate can be silicon or other semiconductive materials known in the art, such as germanium (Ge), silicon carbide (SiC), amorphous silicon carbide (α-SiC), strained Si, SiGe, silicon germanium doped with carbon (SiGe:C), Si alloys, Ge, Ge alloys and combinations thereof alloys of gallium arsenic (GaAs), aluminum arsenic (AlAs), indium gallium arsenic (InGaAs), indium aluminum arsenic (InAlAs), indium aluminum arsenic antimony (InAlAsSb), indium aluminum arsenic phosphorus (InAlAsP), indium gallium arsenic phosphorus (InGaAsP) and combinations thereof. Similarly, the thermistor trace can be made of or contain conductive or semi-conductive material, such as any of the above semiconductors, preferably one or more of silicon carbide, amorphous silicon carbide, diamond, diamond-like carbon (DLC), amorphous germanium, silicon-germanium, or silicon-germanium-boron alloy. The electrically conductive traces can be made of a conductive material such as platinum, aluminum, tungsten, titanium, chromium, gold, copper, silver, or a chromium-gold alloy. The thermistor trace, electrically conductive traces, and feedback heater material can be deposited on the substrate by sputtering.

The polymer superstrate can be made from a non-conductive material, such as epoxy resin, preferably SU-8 photoresist or a polyimide. The feedback heater material can be made of a conductive material, such as containing platinum, aluminum, tungsten, titanium, chromium, gold, copper, silver, or a chromium-gold alloy.

The disclosed nanocalorimeter enables direct determination and understanding of biomolecular events at micro liter volume in a high throughput manner. It also enables comprehensive high-content thermodynamics study in the early stage of drug discovery and formulation. It enables direct, precise, and rapid evaluation of ligand binding with protein or DNA, the folding and unfolding of the large biomolecules like proteins, DNAs, and enzymes of picomolar amount, and determination of a variety of microscale or nanoscale biomolecular processes without labeling or immobilization. It provides a powerful tool to study the membrane proteins, which is often impractical or impossible before.

### BRIEF DESCRIPTION OF THE FIGURES

The patent or application file contains at least one drawing executed in color. Copies of this patent or patent application publication with color drawing(s) will be provided by the Office upon request and payment of the necessary fee.

FIGS. 1A-1B. (A) Schematic view of exemplary nanocalorimeter unit, (B) cross section of the nanocalorimeter unit in (A) at cross point X.

FIGS. 2A-2F. A fabrication process for the nanocalorimeter unit.

FIGS. 3A-3C. (A) Nanocalorimeter device, (B) expanded view of temperature sensor section of device, (C) expanded view of feedback heater section of temperature sensor.

FIGS. 4A-4B. (A) Novel pattern design of low-resistance high-sensitive thermistor in comparison with (B) conventional design.

FIG. 5. Illustration of the fabricated planar structure (a), and SEM micrograph of a typical amorphous SiC (b).

FIG. 6. Gas pressure dependence of density.

FIG. 7. Resistivity variation of SiC films with increasing Ar gas pressure at sputtering power 300 and 400 watts.

FIG. 8. Current-voltage characteristics of thermal sensor with planar structure. The marks in figure represent the measured data while the straight lines represent the fits using least squares approach.

FIG. 9. R-T characteristic of SiC thin films at two power levels of DC magnetron sputtering.

FIGS. 10A-10B. (a) Calibration curves of Resistance vs. Temperature, (b) Resistance ratio of the sensing element vs. temperature.

FIGS. 11A-11B. (A) Simulation of the temperature distribution on the SU8 film, (B) temperature distribution comparison on equilibrium area.

FIGS. 12A-12B. (A) Measured transient response of the device with cap (blue) and without cap (red, thin) when a hot liquid is added to sample area, (B) transient response when the sample drop is subjected to 45 mW heat power with cap.

### DETAILED DESCRIPTION OF THE DISCLOSURE

Disclosed is an ultrasensitive nanocalorimeter device, methods of fabricating such a device, and methods of use thereof. The nanocalorimeter contains thermal equilibrium areas for sample and reference liquids, with thermometers, compensation heater, and electric trace elements fabricated on a free-standing polymer diaphragm membrane. The terms “calorimeter” and “nanocalorimeter” are used interchangeably herein to refer to a device capable of measuring heats of reaction in the range of nanocalories.

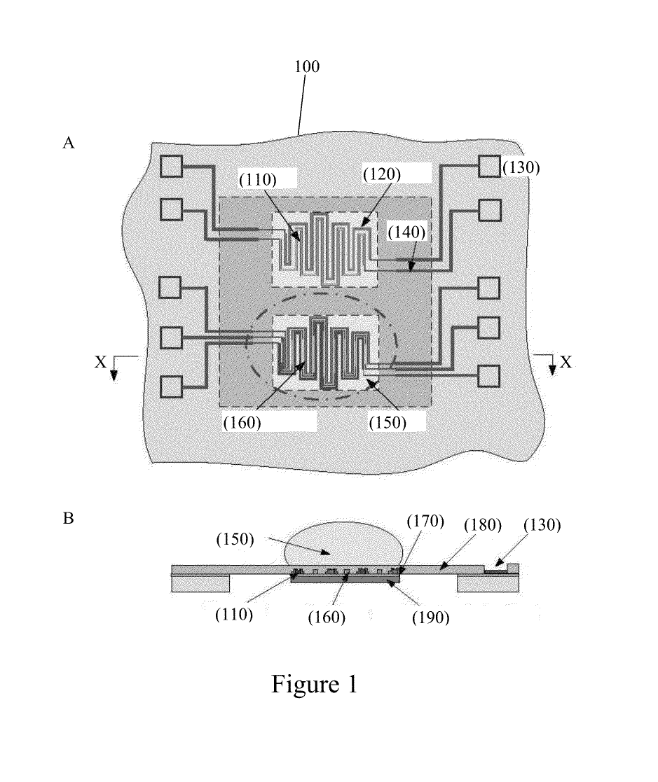

FIG. 1 presents a schematic view of an exemplary nanocalorimeter. The nanocalorimeter unit 110 includes at least two thermal equilibration areas 120, 150 for sample 120 and reference 150 liquids. An important feature of the nanocalorimeter 110 is that the thermistors 110, feedback heater 160, and electric traces 140 are fabricated on a free-standing polymer diaphragm 180. The free-standing membrane 180 significantly decreases the heat transfer from the sample or reference region to other area and reduces the thermal mass of the whole measurement region. Copper islands 190 are formed on the backside of the membrane below the sample and the reference regions to improve temperature uniformities of the thermal equilibration areas. Because of the minimized thermal mass and the improved thermal isolation, the device can have a sufficiently fast time response to allow real-time measurement.

The polymer diaphragm 180 is a thin film membrane that holds the reference and sample. The membrane is “free-standing”, that is, it is the only material connecting the thermal equilibrium areas to the rest of the nanocalorimeter, as shown in FIG. 1B. This “free-standing” membrane is in contrast to other thin film-containing calorimeters known in the art, where the membrane is supported by metal or other conductive material across the entire device. The thin film can be fabricated using spinning and dry etching. The terms “diaphragm” and “membrane” are used interchangeably herein to refer to the thin film portion of the disclosed nanocalorimeter.

The disclosed diaphragm 180 can comprise a plastic material in thin film form, typically ranging from less than 15 microns to approximately 25 microns in thickness for this embodiment, possibly as thin as 2 microns and as thick as 500 microns for some applications. The preferred thickness is about 20 microns. Candidate plastic materials include SU-8 photoresist, polyimide (for example Dupont Kapton® and others), polyester (for example Dupont Mylar®) foil, PolyEtherEtherKetone (PEEK), or PolyPhenylene Sulphide (PPS). Alternatively, in some embodiments, the diaphragm comprises other thin membranes of sufficiently low thermal conductivity, such as SiN and comparable materials. In a preferred embodiment, the diaphragm comprises SU-8 or a polyimide.

The membrane materials employed have very small thermal conductivity so as to minimize or prevent the transfer of energy from a biological sample to the reference liquid or to the base. A small area of high-conductive metal is deposited on the thin film to ensure quick thermal equilibrium inside the sample or reference liquid. The feedback heater (platinum) is fabricated on the sample area for power compensation using lift off process.

High sensitivity micro-thermistors are formed on the membrane in each thermal equilibration area for temperature sensing using physical vapor deposition (PVD) and photolithography technology. They also will be used as main heaters for temperature scanning because of self-heating effect during the measurement. The thermistors detect temperature differences between the sample and reference regions. These thermistors are composed of appropriate materials with high temperature coefficient resistance and low intrinsic noise, such as amorphous silicon (α-SiC), silicon carbide, or diamond. Amorphous silicon thin trace is a preferred material. In one embodiment, a SiC thermistor is fabricated on SU-8 thin film using DC magnetron sputtering. In a further embodiment, a PDMS cover is used to enclose the sample and reference to prevent evaporative heat loss.

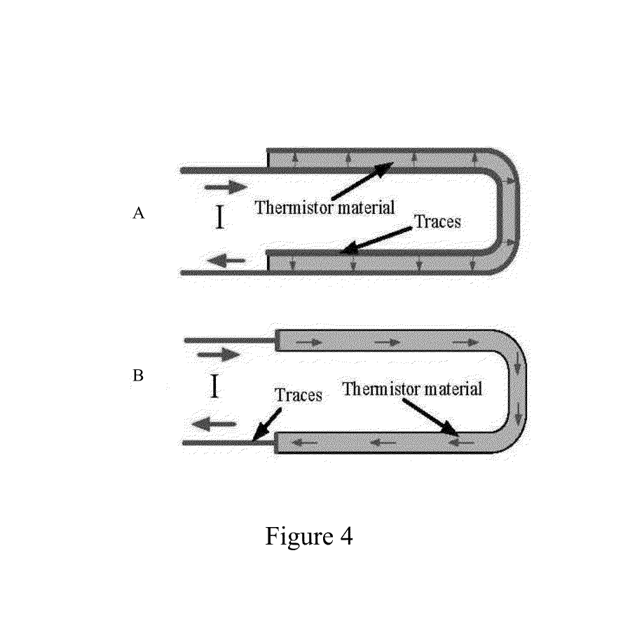

The thermistors disclosed herein are designed with a novel pattern and fabrication of the temperature sensor. The concept is illustrated in FIG. 4. The thermistor trace is sandwiched between additional electrically conductive traces (that is, additional electrical traces are formed on either side of and in continuous contact with the length of the thermistor trace). The electrical traces formed on either side of the thermistor trace can be any electrically conductive material, preferably chromium (Cr), gold (Au) or a chromium-gold alloy. The additional electric traces allow electrical current to flow in a side direction which provides decreased resistance and a corresponding decrease in thermal noise. The temperature difference induced by molecular interactions is sensed by the resistance change of the thermistor(s), which is picked up by a Wheatstone bridge. Using the disclosed “sandwich” thermistor design, the resistance of a 4-mm-long trace of 10 μm×0.2 μm cross-section can be decreased by a factor of 160,000 times, and the corresponding thermal noise (proportional to the square root of the resistance) can be reduced by 400 times. The high temperature sensitivity of the disclosed nanocalorimeter provides measurement of molecular interactions on a microscale level heretofore unmeasurable.

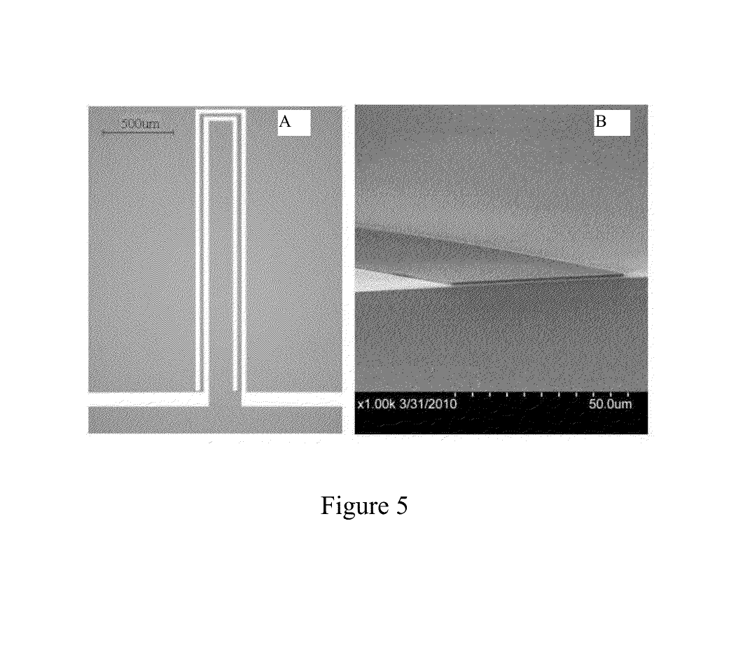

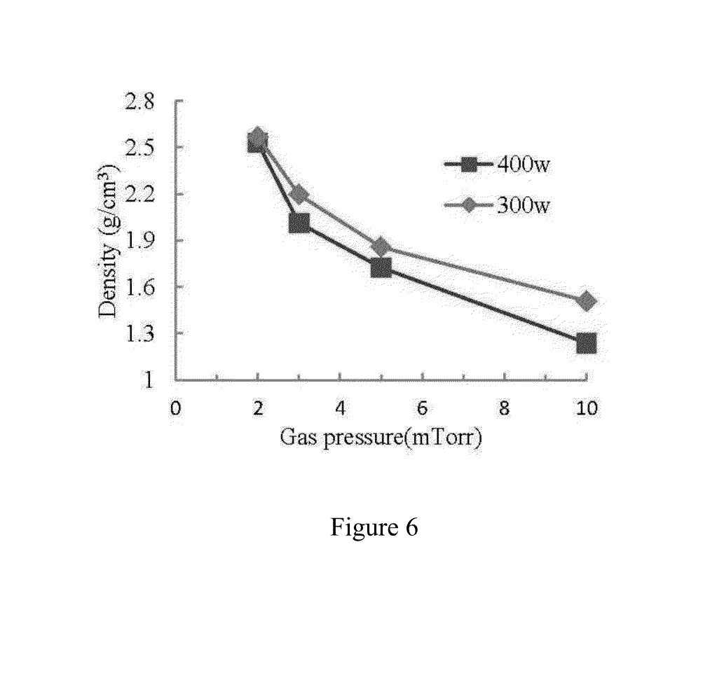

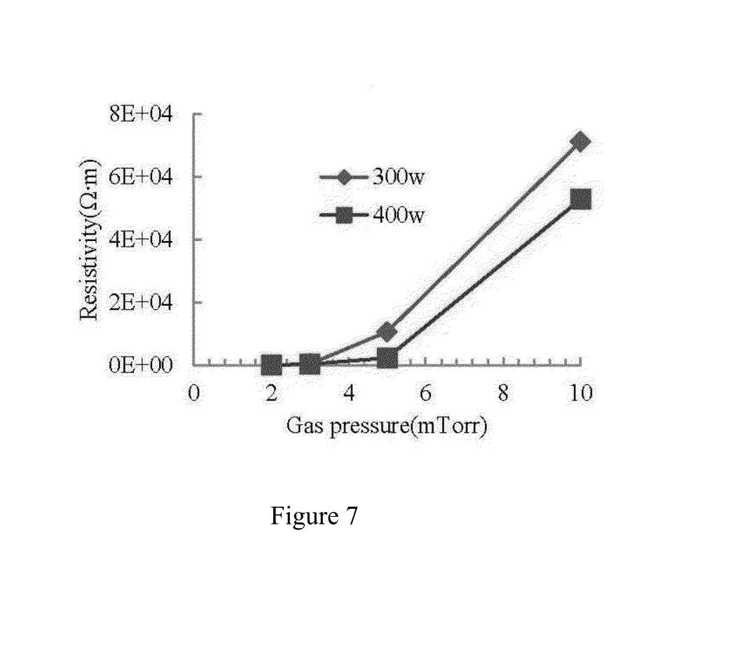

FIG. 5 shows the results of silicon carbide thermistor fabricated using DC magnetron sputtering, which achieved a −2% temperature coefficient resistance (FIG. 6) and a current noise spectral density in the order of 10-11-10-12 A/Hz1/2 (FIG. 7). The overall noise level (including Johnson noise, flicker noise, amplifier noise and quantization noise of data acquisition) for 0.1-10 Hz bandwidth with 10V voltage on the Wheatstone bridge is 0.3 μV, which corresponds to the temperature noise at ˜3 μK for these thermistors. Therefore, the disclosed nanocalorimeter can measure a 10 μK temperature difference between the samples and reference at a signal to noise ratio of Vs/Vnoise=3.3.

During its operation, a constant working voltage is applied to the thermistors which also act as main heaters, to heat up the reference and sample liquids. Temperate difference between the sample and reference cells caused by biomolecular interaction is sensed by thermistors on the membrane and a Wheatstone bridge, and is further compensated by additional heating power to the sample with the feedback heater, which is excess heat capacity Cp. The differential measurement will afford excellent common mode rejection in the sample and reference regions, such as room temperature fluctuations.

Another feature of the disclosed nanocalormeter is combined self-heating and sensing ability. Specifically, the thermistors will not only pick up the signal, but also act as the main heater for temperature scanning. Assuming the resistance of the thermistors is 5000-7500 Ω·m and the bridge voltage Vcc is 10V, then the heating rate for 5 μL aqueous liquid will be about 20-28° C./min, which means that temperature scanning from 0° C. to 100° C. takes only 4-5 minutes, which is faster than a commercial calorimeter.

The temperature difference between the sample and reference regions is detected by a plurality of thermistors on the membrane. The number of thermistors can be 2, 4, 6, or 8. The preferred number of thermistors per nanocalorimeter is four. The temperature difference induced by molecular interactions will be sensed by the resistance change of the thermistor, which will be picked up by a Wheatstone bridge, construction and function of which is known in the art.

A compensation/feedback heater can be fabricated on the thin film using a lift off process. The platinum heating trace can be distributed between the thermistors as shown in FIG. 5. The temperature difference between the sample and reference liquids will be picked up by the Wheatstone bridge, where the microvolt signal is then magnified to over millivolt level, for example with a low noise precision amplifier with a gain of 1000-2000. The real time control is designed to drive the feedback heater to equalize the temperature difference between the sample and reference. For a feedback heater of a resistance of 2,000 Ω·m, the feedback heating power will be 2 nW at 2 mV.

The operation principal is similar to the standard differential scanning calorimeter (DSC). A constant working voltage is applied to the thermistors, which also act as main heaters, to heat up the reference and sample liquids. Temperate difference between the sample and reference cells caused by biomolecular interaction is sensed by thermistors and Wheatstone bridge, and is further compensated by additional heating power to the sample with the feedback heater. The electrical power of feedback heater (and thus excess heat capacity Cp) is recorded, the transition (for example, protein folding) temperature is the one where the maximum peak of Cp occurs, shifted baseline before and after transition is the change of heat capacity ΔCp, and the area under the transition curve is defined as the unfolding enthalpy ΔH. The Gibbs free energy ΔG, entropic ΔS and affinity constant or disassociation constant can be obtained by comparing the unfolding processes of liganded and ligand-free proteins.

Also encompassed in this disclosure is additional elements known in the art for the practice of calorimetry, microcalorimetry, and nanocalorimetry, including, but not limited to, circuitry, other additional electrical elements, analytic programs, and other elements which, although not expressly disclosed herein, are known or available to the skilled practitioner.

This disclosure further provides arrays comprising a plurality of nanocalorimeters according to the invention. In one embodiment, the array is of 8×12 form in the standard microplate footprint with center-to-center distance of 9 mm. Such arrays are suitable, for example, in high-throughput screening methods that use nanocalorimeters in the study, discovery, and development of new compounds, materials, chemistries, and chemical processes, as well as high-throughput monitoring of compounds or materials, or high-throughput monitoring of the processes used to synthesize or modify compounds or materials.

This disclosure further provides methods of fabrication of high-sensitivity nanoscale devices for measuring molecular interactions. The fabrication methods include, but are not limited to, the steps of:
h. providing a semiconductor substrate;
i. patterning the substrate and etching the back side of the substrate to define a diaphragm window;
j. forming a thermistor trace on the front side of the substrate over the area defining the diaphragm window;
k. depositing feedback heater material on the front side of the substrate over the area defining the diaphragm window;
l. forming electrically conductive traces along both sides of the thermistor trace to sandwich the thermistor trace between electrically conductive trace;
m. depositing a polymer superstrate on the front side of the substrate to encapsulate the thermistor trace, feedback heater, and electrically conductive trace; and
n. further etching the area defining the diaphragm window on the back side of the substrate to form a free-standing polymer diaphragm.

The method can further include the step of: (h) forming a copper island on the back side of the substrate within the area defining the diaphragm window.

According to this method, the semiconductor substrate can be silicon or other semiconductive materials known in the art, such as germanium (Ge), silicon carbide (SiC), amorphous silicon carbide (α-SiC), strained Si, SiGe, silicon germanium doped with carbon (SiGe: C), Si alloys, Ge, Ge alloys and combinations thereof alloys of gallium arsenic (GaAs), aluminum arsenic (AlAs), indium gallium arsenic (InGaAs), indium aluminum arsenic (InAlAs), indium aluminum arsenic antimony (InAlAsSb), indium aluminum arsenic phosphorus (InAlAsP), indium gallium arsenic phosphorus (InGaAsP) and combinations thereof. Similarly, the thermistor trace can be made of or contain conductive or semi-conductive material, such as any of the above semiconductors, preferably one or more of silicon carbide, amorphous silicon carbide, diamond, diamond-like carbon (DLC), amorphous germanium, silicon-germanium, or silicon-germanium-boron alloy. The electrically conductive traces can be made of a conductive metal such as platinum, aluminum, tungsten, titanium, chromium, gold, copper, silver, or a chromium-gold alloy. As used herein, a “metal” is an electrically conductive material, wherein in metals atoms are held together by the force of metallic bond; and the energy band structure of metal's conduction and valence bands overlap, and hence, there is no energy gap.

The polymer superstrate can be made from a non-conductive material, such as epoxy resin, preferably SU-8 photoresist or a polyimide. The feedback heater material can be made of a conductive material, such as containing platinum, aluminum, tungsten, titanium, chromium, gold, copper, silver, or a chromium-gold alloy.

The thermistor trace, electrically conductive traces, and feedback heater material can be deposited on the substrate by sputtering.

This disclosure also provides methods of use of nanocalorimeters and nanocalorimeter arrays to measure thermodynamic changes induced by molecular interactions. Such methods can be used to measure, for example, the strength of binding between a first molecule and a second molecule, by measuring the thermodynamic changes induced by interaction of the two molecules placed together in or on the disclosed nanocalorimeter. In addition, the disclosed nanocalorimeters and arrays can be used to measure folding and/or unfolding of biomolecules, by measuring the thermodynamic changes induced by conformational changes of the biomolecule. Further examples include measuring membrane protein interactions, such as binding of a molecule or ion to a membrane protein in a lipid membrane or micelle.

Similarly, the disclosed nanocalorimeters and nanocalorimeter arrays can detect enthalpic changes, such as enthalpic changes arising from reactions, phase changes, changes in molecular conformation, and the like.

The disclosed devices are useful, for example, in medical diagnosis, drug screening and formulation studies, and also have broad applications in biological and biomedical research.

To practice the disclosed methods, a fluid sample containing biological material is placed on the sample area of a nanocalorimeter. The biological material can include, but is not limited to, tissue, cells, membrane preparations, proteins, peptides, nucleic acids, organic compounds or molecules, or any combination thereof. The sample volume can be 1-10 μl, preferably 5 μl or less, even more preferably 2-5 μl. Two or more samples, containing two or more distinct types of biological material, may be added to the nanocalorimeter to measure interactions between the materials contained in the samples. In addition, a reference fluid is placed in the reference area of the nanocalorimeter. Thermal fluctuations in the biological sample are measured against the reference fluid, and the changes in the sample temperature can be correlated with the interaction which is desired to be studied.

In connection with the methods of measuring thermal changes associated with molecular interactions, this disclosure further encompasses programs, software, or computer instructions embodied or stored in a computer or machine usable or readable medium, which causes the computer or machine to perform the measurement and analytic steps of the method when executed on the computer, processor, and/or machine. A program storage device readable by a machine, e.g., a computer readable medium, tangibly embodying a program of instructions executable by the machine to perform the methods described in the present disclosure is also provided.

The system and method of the present disclosure may be implemented and run on a general-purpose computer or special-purpose computer system. The computer system may be any type of known or will be known systems and may typically include a processor, memory device, a storage device, input/output devices, internal buses, and/or a communications interface for communicating with other computer systems in conjunction with communication hardware and software, etc.

The computer readable medium could be a computer readable storage medium or a computer readable signal medium. Regarding a computer readable storage medium, it may be, for example, a magnetic, optical, electronic, electromagnetic, infrared, or semiconductor system, apparatus, or device, or any suitable combination of the foregoing; however, the computer readable storage medium is not limited to these examples. Additional particular examples of the computer readable storage medium can include: a portable computer diskette, a hard disk, a magnetic storage device, a portable compact disc read-only memory (CD-ROM), a random access memory (RAM), a read-only memory (ROM), an erasable programmable read-only memory (EPROM or Flash memory), an electrical connection having one or more wires, an optical fiber, an optical storage device, or any appropriate combination of the foregoing; however, the computer readable storage medium is also not limited to these examples. Any tangible medium that can contain, or store a program for use by or in connection with an instruction execution system, apparatus, or device could be a computer readable storage medium.

The terms “computer system” and “computer network” as may be used in the present application may include a variety of combinations of fixed and/or portable computer hardware, software, peripherals, and storage devices. The computer system may include a plurality of individual components that are networked or otherwise linked to perform collaboratively, or may include one or more stand-alone components. The hardware and software components of the computer system of the present application may include and may be included within fixed and portable devices such as desktop, laptop, and/or server. A module may be a component of a device, software, program, or system that implements some “functionality”, which can be embodied as software, hardware, firmware, electronic circuitry, etc.

The present disclosure is further illustrated by the following non-limiting examples.

### EXAMPLES

### Example 1

### Fabrication of a Nanocalorimeter

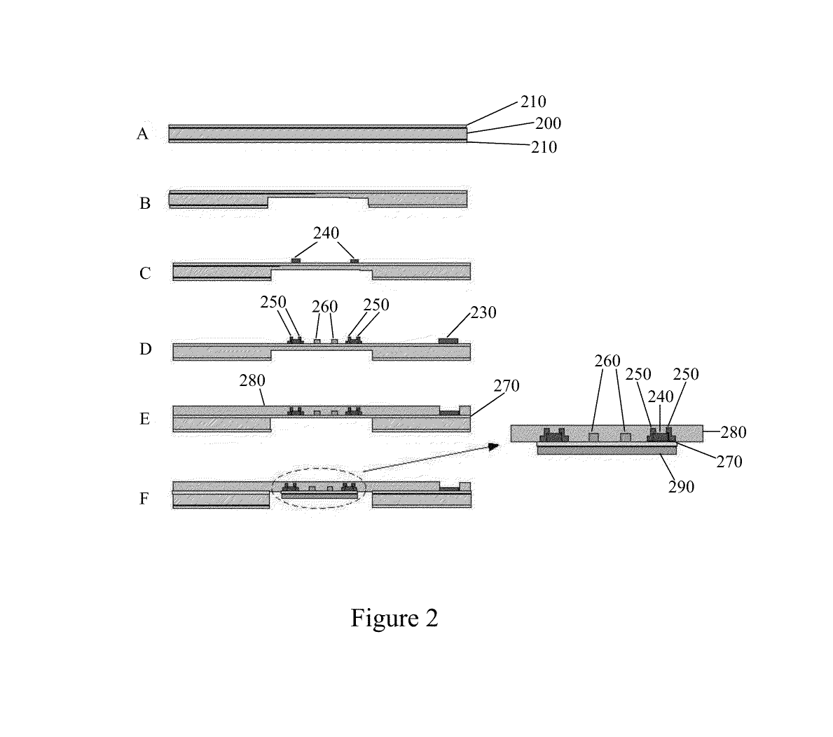

FIG. 2 shows an exemplary fabrication process. The process started with a silicon wafer 200 with a 500 nm silicon nitride (Si₃N₄) core, covered on the front side with 50 nm aluminum oxide (Al₂O₃) 210 and covered on the backside with 200 nm chromium (Cr), which were evaporated onto the wafer to serve as stop layer and mask layer, respectively, for the later plasma etch processes (FIG. 2A). A photolithography step was then performed on the backside of the wafer to define a 5.5×7.5 mm² diaphragm window (FIG. 2B). The photoresist pattern was transferred to the Cr and then Si₃N₄ layers using wet etching (chromium etchant 1020, Transene Company Inc.) and plasma etching techniques, respectively. The Si exposed in the windows was thinned down to about 100 μm using a cryogenic deep reaction ion etch (DRIE) process in an Oxford Plasmalab 100 ICP (inductively coupled plasma) reactor. A 100-nm-thick α-SiC film was then deposited onto the Al₂O₃ surface in a magnetron sputtering deposition tool (2 mTorr argon gas, 400 watts DC power), and patterned using photolithography and ICP etch techniques, to form four temperature sensing thermistor elements 240 on top of the diaphragm window (FIG. 2C). The SiC film obtained has a resistivity of 10 Ω·m.

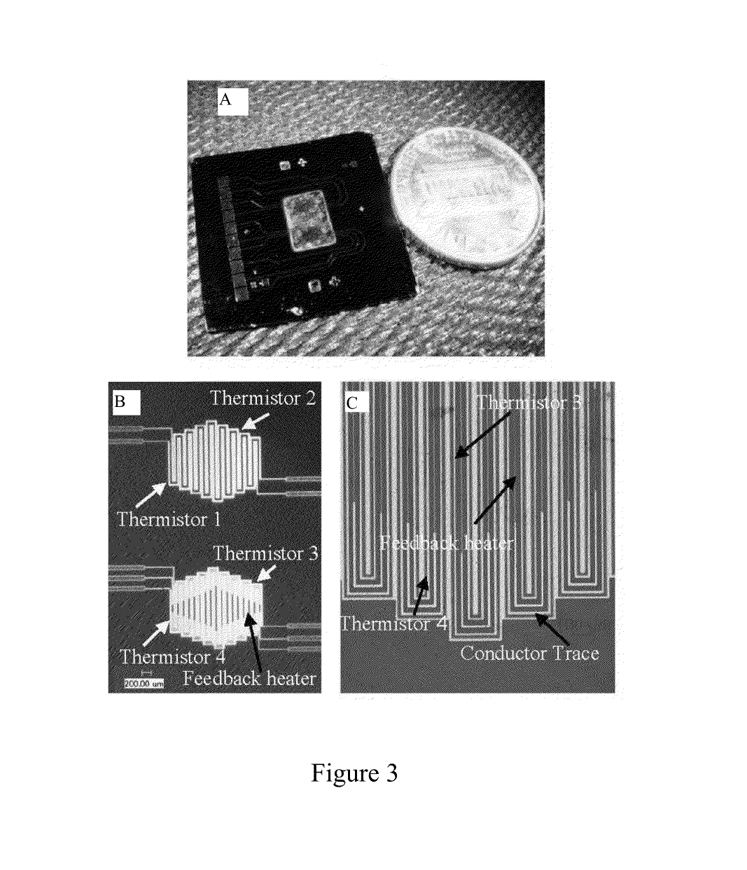

The metal layers were deposited and patterned via lift-off process. Here, platinum (Pt) was chosen as the feedback heater 260 material due to its stable thermal property and good compatibility, and a 10-nm-thick titanium (Ti) layer was introduced to improve the adhesion between platinum and Al₂O₃. The 100-nm-thick platinum layer was sputtering-deposited at 5 mTorr argon gas pressure and 200 watts DC power. This process was carried out sequentially without breaking the vacuum in the sputtering chamber. A stack of 10 nm chromium and 200 nm gold was deposited and patterned to form electric traces 250 and electrodes 230, respectively (FIG. 2D). To encapsulate the thermometers 240, feedback heater 260, and electric traces 250, a 20-μm-thick epoxy resin (cross-lined SU-8 photoresist) superstrate 280 covers the front side of whole device (FIG. 2E). In order to form a free-standing diaphragm, the Si layer underneath the diaphragm was etched away using SF6/O2 plasma. Finally, 1-μm-thick copper was deposited on the backside of the membrane with the presence of a shadow mask to form two thermal conductive islands 290 (FIG. 2F). A PDMS (polydimethylsiloxane) cover was then used to encapsulate the entire device. After oxygen plasma treatment on the bonding surfaces of the PDMS and SU-8 film, the PDMS cover can seal the device easily. FIG. 3 shows an exemplary nanocalorimeter device including sensor and Pt heater.

The fabricated temperature sensing layer of the nanocalorimeter is shown in FIG. 5(a). Nominally 150 nm SiC film was deposited at comparatively low temperature via DC magnetron sputtering deposition using a sintered SiC target (purity 99.95%). Deposition of SiC thin film was performed in a Kurt Lesker PVD 75 magnetron sputtering deposition tool. DC power was applied to a 3 inch diameter SiC target in a pure argon (Ar) atmosphere. Amorphous SiC thin film was deposited on to Si substrates. Prior to sputtering process, the vacuum chamber was evacuated to 2×10⁻⁶ Torr and Ar working pressure was maintained by means of a sorption pump. The properties of the thermistor thin films depend on the Ar pressure and the power. The SiC film was patterned by ICP etching with a gas mixture of CHF3 (11 sccm), SF6 (43 sccm) and O₂ (6 sccm) (FIG. 5(b)). The sample temperature was maintained at 20° C., and RF power W1=150 watt, ICP power W2=900 watt. In the next step, a 300 nm aluminum was deposited by DC sputtering at a power W=300 watt and pressure P=3 mTorr. Finally, a lithographic step and wet etching is performed to obtain electrical traces, pads and contacts for contacting the sensing layer.

The properties of SiC film are sensitive to the deposition conditions. A parametrical study of DC sputtering SiC thin film was conducted to obtain the optimal parameter settings for Ar gas pressure from 2 mTorr to 10 mTorr and power from 200 watt to 500 watt, as summarized in Table 1.

TABLE 1
Deposition conditions for amorphous silicon
carbide film and associated film thickness

| # | Power(watt) | Pressure(mTorr) | Thickness(nm) |
|---|---|---|---|
| 1 | 300 | 2 | 102.5 |
| 2 | | 3 | 110 |
| 3 | | 5 | 130 |
| 4 | | 10 | 160 |
| 5 | 400 | 2 | 98 |
| 6 | | 3 | 120 |
| 7 | | 5 | 140 |
| 8 | | 10 | 195 |

In order to obtain low intrinsic noise resistor, the electrical resistivity p of the order of 1-Ω·m are desired for the planar structure in our nanocalorimeter. FIG. 7 shows the relation of the SiC resistivity and Ar gas pressure for sputtering power 300 and 400 watts. The resistivity of the amorphous SiC films sharply increases from 10.4 Ω·m to approximately 6.3×104 Ω·m when the Ar gas pressure increases from 2 mTorr to 10 mTorr at sputtering power 300 watts. Lower resistivity can be obtained at higher sputtering power. The lowest resistivity of 9.5 Ω·m at room temperature is obtained at 400 watt sputtering power.

The device was fabricated on a polymer membrane with four thermistor elements for differential temperature sensing and a feedback heater for power compensation. In order to increase the sensitivity and reduce the noise in temperature sensing, SiC film was prepared at various sputtering power and working gas pressure. The results show the deposition parameters significantly influence on the physical properties of SiC film. It presents an electrical resistivity of ρ≈10 Ω·m at room temperature when the gas pressure is 2 mTorr and power is 300 watt or 400 watt. A novel design is presented to attain reasonable high-sensitive low-noise thermistor. The measurement results show the SiC thermo-sensing material has advantages in temperature sensitivity (TCR −2.04%/K) and noise characteristics. The TCR of the Pt feedback heater is 0.12%/K with excellent linearity. Thermal performance of a fabricated nanocalorimeter is studied in simulation and experiments. The results show the device has nanowatt thermal power sensitivity and a long time constant to hold thermal energy, which promise ultra high sensitive nanocalorimetry for biological process study.

### Example 2

### Characteristics of Thermistor Materials

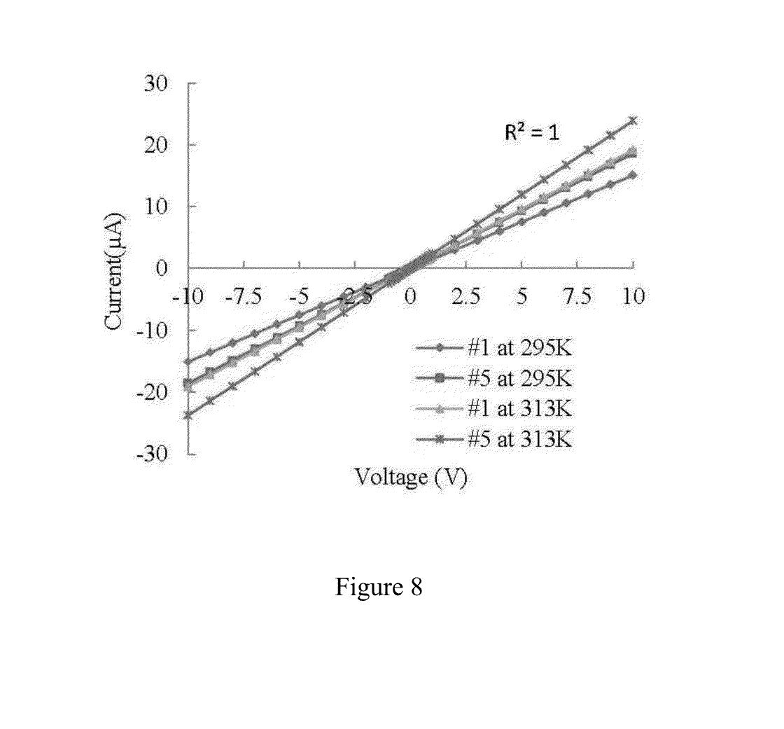

The performance of the thermistor SiC was characterized by the ohmicity of resistance, temperature coefficient of resistance (TRC), and noises. The inventors measured the current-voltage relation at temperature 295K and 313K using a Keithley 6517A electrometer, with the applied voltages varied from −10 V to 10 V. The measured current-voltage I-U curves are shown in FIG. 8, which indicate the current-voltage characteristics are linear and symmetrical for planar configuration at different current, and the resistance material is ohmic.

For temperature coefficient of resistance (TRC), the inventors measured temperature dependence of the resistance in 20-100° C. range in a Lakeshore probe station using an accurate sourcemeter. Since electrical conduction in amorphous materials is a thermally activated process, the temperature dependence on the resistance of semiconductor thermistors can be approximately represented using a relation of the form

R=R0exp(Ea/kbT) (1)

where R0 is the prefactor resistance, the kb is the Boltzmann's constant, and Ea the activation energy, which is related to the TCR by α=−Ea/kT2. Therefore, the TRC can be calculated from the slope of InR and 1/T plots, where the slope is Ea/kb.

InR=InR0+Ea/kbT (2)

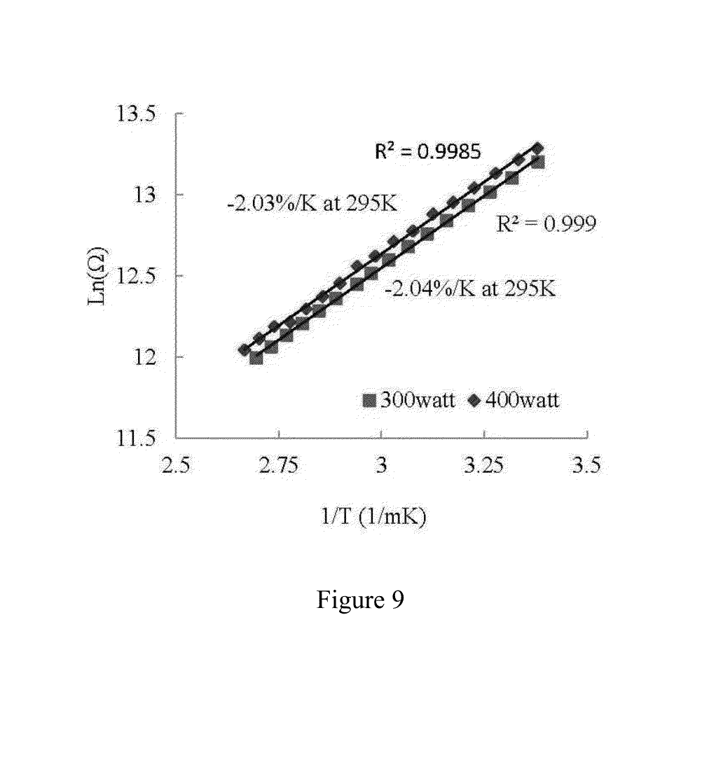

FIG. 9 shows temperature coefficients of resistance at 25° C. are −2.03%/K, and −2.04%/K for these two samples.

Noise is a major concern for any high-resolution nanocalorimeters. In this study we investigated the noise spectra using a low-noise current preamplifier and HP 35670 dynamic signal analyzer. The noise power spectral density of a DC biased amorphous SiC thin film consists of components of Johnson thermal noise and 1/f noise. The thermal noise power spectral density term can be estimated using ST=4k_{b}RT, where R is the resistance of SiC thin film, T is temperature. The relationship between the power spectral density and 1/f parameter is given as S1/f=KfI²R²/f^{β}, where Kf is 1/f noise parameter, I is current across the film, β is the empirical factor, and f is the frequency. When the measurement system is used, an additional instrument noise (Sv) can be generated through the preamplifier, biasing circuit, and dynamic analyzer. The total noise can be expressed:

Sₜₒₜₐₗ(f)=4k_{b}RT+KfI²R²/f^{β}+Sv=KfI²R²/f^{β}+Svb (3)

where the sum of the test sample Johnson thermal noise and the instrument noise are denoted as background noise Svb.

The background noise and the total noise were measured separately. The background noise was measured when the system was operating with no DC voltage across the thin film. Subtraction of both from the total noise obtains the 1/f noise. The thin film was placed in a well-shielded aluminum box. The current from the thin film was fed to a low current preamplifier (Stanford research systems SR570) which is battery powered for low intrinsic noise, and provides the biasing of the sample. The amplifier is also equipped with a comprehensive set of low-pass, high-pass and band-pass filters. In this application, the inventors set it as the band pass filter of the frequency range of interest, namely 0.03 Hz to 30 Hz. The temporal current fluctuations were recorded with the signal analyzer HP 35670A and a noise spectrum was taken after 30 averages.

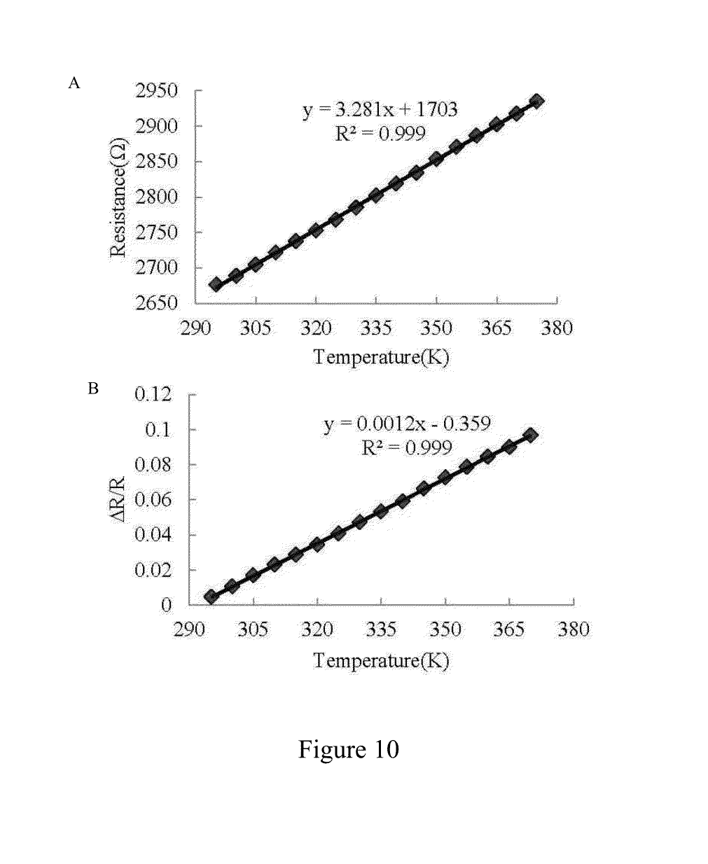

The current noise spectral density of one sample at different applied biases (0V, 1V, 2V) is shown in FIG. 10. It can be seen that with no bias, the background noise was measured to be 10-11-10-13 A/Hz1/2 in a frequency range of 0.1-10 Hz. The noises measured at 1 V and 2 V are similar to the background noise and 1/f noise dominates at 0.1-10 Hz. By subtracting background noise from the total noise, we observed that a 1/f current noise spectral density in the 500 k SiC film is approximately 10-13 A/Hz1/2. In addition, the spectral density of thermal noise can be calculated in the order of 10-13 A/Hz1/2. For a bandwidth of 0.1-10 Hz, the noise will be 0.2˜0.307, which is corresponding to the temperature noise at 2˜3 μK for these thermistors. Therefore, a temperature of the SiC film of the order of 10 μK can be achieved and signal to noise ratio can be 4˜5.

### Example 3

### Characteristics of the Feedback Heater

Due to the thermal stability and good linear temperature coefficient, platinum was chosen as the feedback heater and temperature sensor (to monitor the temperature scanning). The properties of the sputtered Pt film also depend on the fabrication parameters. To assure the accuracy of power compensation and temperature measurement, it is necessary to calibrate the Pt film.

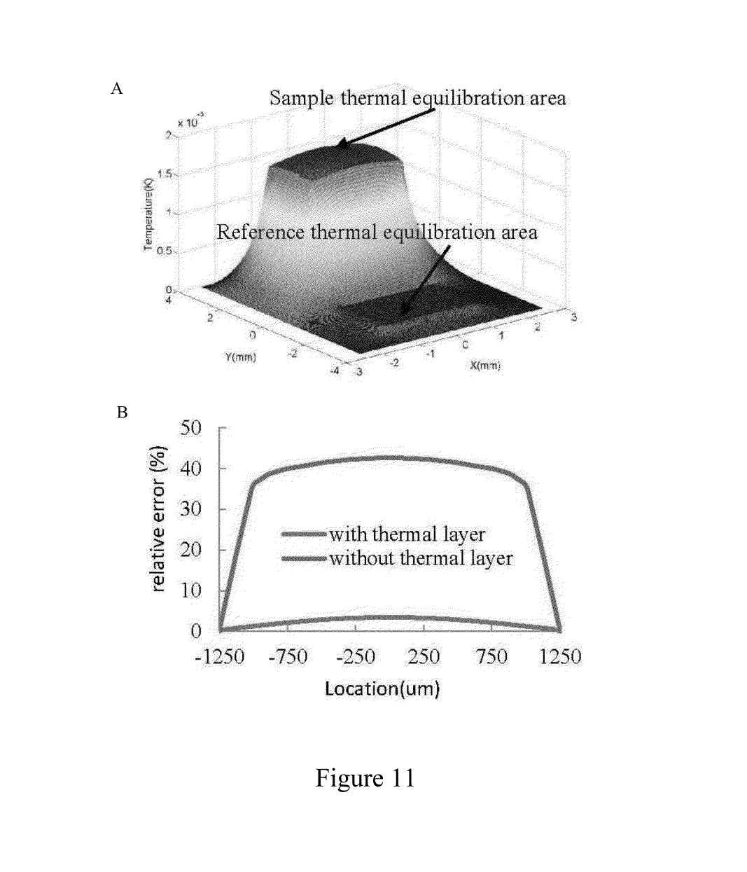

The device was placed in a Lakeshore probe station. The inventors performed the current-voltage measurement at different temperatures using an electrometer in the voltage range from −1 V to 1 V. FIG. 11 shows the electrical resistance and its variation in 20-100° C. range, in which ΔR=R(Ti)−R(T0). The results demonstrate that the resistance varied linearly with the temperature and TCR is independent of temperature. In this work, the temperature coefficient of resistance was 0.12%/° C., which is lower than that of bulk pure platinum (0.39%/° C.). This is possibly due to the porosity of the sputtered platinum film

### Example 4

### Characteristics of Thermal Responses

Simulations and experiments are carried out to study the thermal responses the nanocalorimeter, including the power resolution, temperature uniformity, and transient and steady response time.

To pursue ultra-sensitive low-noise temperature sensing at microliter sampling volume, it is necessary to have large thermal time constant, which means small parasitic energy loss. FIG. 9 illustrates the heat flow paths, including conduction through the film and air. In this illustration the finite element analysis program ANSYS was used for the thermal and structure simulation. The simulation was performed assuming a SU8 membrane thickness of 20 μm and a thermal island (copper) thickness of 1 μm. A 5 nW power is applied in the sample bio buffer (phosphate buffered saline, PBS solution), and 0 nW to the reference drop. The time response of the temperature difference of liquid drops demonstrated an excellent time constant of approximately 35 seconds.

On a thin film with a 5 nW power applied, and with a temperature difference between the sample and reference thermal equilibration area of greater than 10 μK (micro Kelvin), the copper thermal conductive island can effectively maintain the uniformity of the temperature in the measurement region within 1 μK variance; thus, the temperature gradient in the thermal equilibration area is small. Accordingly, the disclosed nanocalorimeter can achieve a thermal resolution of 5 nW.

FIG. 11B compares the temperature along the central line in the equilibrium area with and without a conductive thermal island on the backside of the membrane, where the relative error is defined as the normalized temperature variance. The 1 μm copper thermal conductive island was found to effectively maintain the uniformity of the temperature in the measurement region.

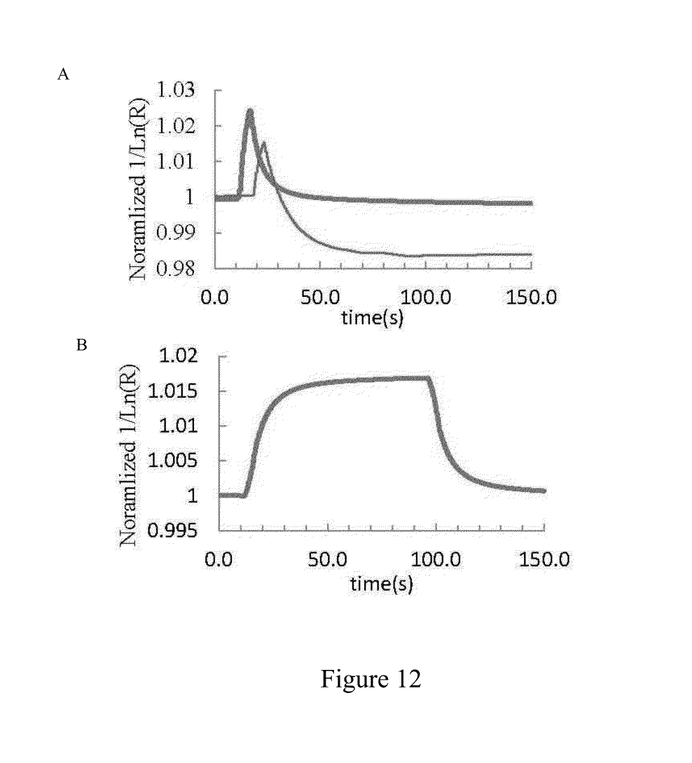

FIG. 12A shows comparison of the temperature changes measured by the thermistor with (blue) and without (red) PDMS cap when a hot drop (˜50° C.) was added to the sample measurement area. When a cap is present, the temperature increases very fast, and decrease rate is relative slower. After the system reached a steady state, the baseline doesn't shift. On the contrary, the baseline shifted almost 2% without a polymer cap. The reason is that the energy transport from the drop to the environment air via evaporation, the balance of conduction and evaporation contribute to the baseline shift. Therefore FIG. 12B illustrates how the PDMS cap can minimize the liquid evaporation.

To characterize the device's transient thermal response to the heating power, two 3 μl drops were added on the sample and reference measurement area. At the beginning, the device is in a steady state. A 100 s electrically generated pulse was applied to the feedback Pt heater. The 100 s electrical pulse 45 mW was enough to allow the system to reach a steady state. FIG. 12B shows the time constant of thermal dissipation is almost 8.4 s, where longer time indicates smaller parasitic energy loss.

What is claimed is:

1. A nanocalorimeter comprising: a polymer diaphragm with a plurality of thermal equilibrium areas, each thermal equilibrium area comprising at least one compensation heater and at least one microthermistor formed from a microthermistor trace sided by additional electrically conductive traces.

2. The nanocalorimeter of claim 1, wherein the polymer diaphragm is free-standing.

3. The nanocalorimeter of claim 1, wherein the polymer diaphragm comprises epoxy resin.

4. The nanocalorimeter of claim 3, wherein the epoxy resin is selected from SU-8 or a polyimide film.

5. The nanocalorimeter of claim 1, wherein the microthermistor trace comprises one or more of silicon carbide, amorphous silicon carbide, diamond, amorphous germanium, or silicon-germanium-boron alloy.

6. The nanocalorimeter of claim 1, wherein the additional electrically conductive traces are formed along either side of the microthermistor trace and comprise chromium, gold, or a chromium-gold alloy.

7. The nanocalorimeter of claim 1, comprising four microthermistors.

8. The nanocalorimeter of claim 1, wherein the polymer diaphragm further comprises a copper island formed on the underside of each thermal equilibrium area.

9. The nanocalorimeter of claim 1, wherein the epoxy resin is SU-8 with a thickness of about 20 μm.

10. The nanocalorimeter of claim 1, wherein the nanocalorimeter can measure thermal fluctuations of 10 μK or less.

11. The nanocalorimeter of claim 1, further comprising a cover made of polydimethylsiloxane (PDMS).

12. A nanocalorimeter array comprising a plurality of nanocalorimeters according to claim 1.

13. The nanocalorimeter array of claim 12, wherein the array is used for high-throughput measurements.

14. A method of measuring thermodynamic changes induced by molecular interactions, comprising applying a sample of biological material to the nanocalorimeter of claim 1 and measuring the change in temperature resulting from the molecular interaction.

15. The method of claim 14, wherein said sample has a volume of 5 μl or less.

16. A method of fabricating a nanocalorimeter, comprising the steps of:
a. providing a semiconductor substrate;
b. patterning said substrate and etching the back side of said substrate to define a diaphragm window;
c. forming a thermistor trace on the front side of said substrate over the area defining said diaphragm window;
d. depositing feedback heater material on the front side of said substrate over the area defining said diaphragm window;
e. forming electrically conductive traces along either side of said thermistor trace to sandwich said thermistor trace between electrically conductive trace;
f. depositing a polymer superstrate on the front side of said substrate to encapsulate the thermistor trace, feedback heater, and electrically conductive trace; and
g. further etching the area defining said diaphragm window on the back side of said substrate to form a free-standing polymer diaphragm.

17. The method of claim 16, wherein said thermistor trace comprises one or more of silicon carbide, amorphous silicon carbide, diamond, amorphous germanium, or silicon-germanium-boron alloy.

18. The method of claim 16, wherein said electrically conductive traces comprise chromium, gold, or a chromium-gold alloy.

19. The method of claim 16, wherein said thermistor trace, electrically conductive traces, and feedback heater material are deposited on said substrate by sputtering.

20. The method of claim 16, wherein said polymer superstrate comprises an epoxy resin.

21. The method of claim 20, wherein said epoxy resin comprises SU-8 photoresist or a polyimide.

22. The method of claim 16, further comprising the step of: (h) forming a copper island on the back side of said substrate within the area defining said diaphragm window.

23. The method of claim 16, wherein said feedback heater material comprises platinum.
